(19) United States
(12) Patent Application Publication
(10) Pub. No.: US 2014/0120685 A1
(43) Pub. Date: May 1, 2014

(54) PHASE-CHANGE MEMORY DEVICE AND METHOD FOR FABRICATING THE SAME

(71) Applicant: SAMSUNG ELECTRONICS CO., LTD., Gyeonggi-do (KR)

(72) Inventors: Seong Hoon JEONG, Seongnam-si (KR); Yoongoo KANG, Yongin-si (KR); Ho-Kyun AN, Seoul (KR); KONGSOO LEE, Hwaseong-si (KR); JAEJONG HAN, Seoul (KR)

(73) Assignee: SAMSUNG ELECTRONICS CO., LTD., Gyeonggi-do (KR)

(21) Appl. No.: 13/791,870

(22) Filed: Mar. 8, 2013

(30) Foreign Application Priority Data
Oct. 30, 2012 (KR) 10-2012-0121385

(51) Int. Cl. H01L 45/00

(52) U.S. Cl. CPC H01L 45/16
USPC 438/382

(57) ABSTRACT

A semiconductor device and method of forming a semiconductor device is disclosed. The method includes forming a first ion-implanted layer having an amorphous state in a substrate; forming an impurity region of a first conductive type in the substrate; forming a semiconductor pattern on the substrate; forming a first doped region of the first conductive type in the semiconductor pattern; and forming a second doped region of a second conductive type contrary to the first conductive type in the semiconductor pattern. The first ion-implanted layer is formed by implanting carbons ions or germanium ions in the substrate.

### CROSS-REFERENCE TO RELATED APPLICATIONS

This U.S. non-provisional patent application claims priority under 35 U.S.C. §119 to Korean Patent Application No. 10-2012-0121385, filed on Oct. 30, 2012, in the Korean Intellectual Property Office, the entire contents of which are hereby incorporated by reference.

### BACKGROUND

The present disclosure relates to semiconductor devices and methods of manufacturing the same and, more particularly, to a phase change memory device and methods of manufacturing the phase change memory device. More particularly, the present disclosure relates to a phase change memory device having improved electrical characteristics and reliability and a method of manufacturing the phase change memory device.

Semiconductor memory devices are generally divided into volatile semiconductor memory devices such as dynamic random access memory (DRAM) devices or static random access memory (SRAM) devices, and non-volatile semiconductor memory devices such as flash memory devices or electrically erasable programmable read only memory (EEPROM) devices. The volatile semiconductor memory device loses data stored therein when power is off. The non-volatile semiconductor memory device keeps stored data even if power is out.

Among the non-volatile semiconductor memory devices, the flash memory device has been widely employed in various electronic apparatuses such as a digital camera, a cellular phone, an MP3 player, etc. Since a programming process and a reading process of the flash memory device take a relatively long time, technologies to manufacture a novel semiconductor memory device, for example a magnetic random access memory (MRAM) device, a ferroelectric random access memory (FRAM) device, and a phase-change random access memory (PRAM) device, have been constantly developed.

### SUMMARY

The present disclosure relates to semiconductor devices and methods of manufacturing the same.

In one embodiment, a method of forming a phase change memory device is disclosed. The method includes forming a first ion-implanted layer having an amorphous state in a substrate; forming an impurity region of a first conductive type in the substrate; forming a semiconductor pattern on the substrate; forming a first doped region of the first conductive type in the semiconductor pattern; and forming a second doped region of a second conductive type contrary to the first conductive type in the semiconductor pattern. The first ion-implanted layer is formed by implanting carbons ions or germanium ions in the substrate.

In another embodiment, a method of manufacturing a phase-change memory device, includes providing a substrate; forming an impurity region of a first conductive type in the substrate, the impurity region extending from the top surface of the substrate into the substrate; forming a semiconductor pattern on the substrate; forming a first doped region of the first conductive type in the semiconductor pattern; forming a layer having an amorphous state in the substrate; and forming a second doped region of a second conductive type contrary to the first conductive type in the semiconductor pattern. The layer controls the amount of doping that occurs at least in the second doped region.

In another embodiment, a semiconductor device includes a substrate; a first ion-implanted layer in the substrate, the first ion-implanted layer having an amorphous state;

an impurity region in the substrate, the impurity region of a first conductive type; a semiconductor pattern on the substrate; a first doped region of the first conductive type in the semiconductor pattern; and a second doped region of a second conductive type contrary to the first conductive type in the semiconductor pattern. The first ion-implanted layer includes implanted carbon ions or germanium ions in the substrate.

### BRIEF DESCRIPTION OF THE DRAWINGS

Example embodiments will be more clearly understood from the following brief description taken in conjunction with the accompanying drawings. FIGS. 1 through 20 represent non-limiting, example embodiments as described herein.

FIG. 1 is a circuit diagram illustrating a portion of a cell array region of a phase change memory device according to exemplary embodiments.

FIGS. 2 through 10 are cross-sectional views illustrating a method of manufacturing a phase change memory device according to exemplary embodiments.

FIG. 11 is a graph of an exemplary doping concentration profile according to the height of the PN junction diode.

FIGS. 12 through 17 are cross-sectional views illustrating a method of manufacturing a phase change memory device according to exemplary embodiments.

FIGS. 18a through 18c are graphs illustrating characteristics of a phase change memory device according to exemplary embodiments.

FIG. 19 is a schematic block diagram illustrating an example of computing systems including a semiconductor memory device according to the exemplary embodiments.

FIG. 20 is a schematic block diagram illustrating an example of memory cards including a semiconductor device according to exemplary embodiments.

### DETAILED DESCRIPTION

The present disclosure will now be described more fully hereinafter with reference to the accompanying drawings, in which exemplary embodiments are shown. The advantages and features of the present disclosure and methods of achieving them will be apparent from the following exemplary embodiments that will be described in more detail with reference to the accompanying drawings. It should be noted, however, that the inventive concept is not limited to the following exemplary embodiments, and may be implemented in various forms. In the drawings, embodiments are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views. Accordingly, shapes of the exemplary views may be modified according to manufacturing techniques and/or allowable errors. Therefore, the embodiments disclosed herein are not limited to the specific shape illustrated in the exemplary views, but may include other shapes that may be created according to manufacturing processes. Areas exemplified in the drawings have general properties, and are used to illustrate specific shapes of elements. Thus, this should not be construed as limiting the scope of the inventive concept.

It will be also understood that although the terms first, second, third etc. may be used herein to describe various elements, these elements should not be limited by these terms. Unless indicated otherwise, these terms are only used to distinguish one element from another element. Thus, a first element in some embodiments could be termed a second element in other embodiments without departing from the teachings disclosed herein. Exemplary embodiments of aspects explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to limit the scope of example embodiments.

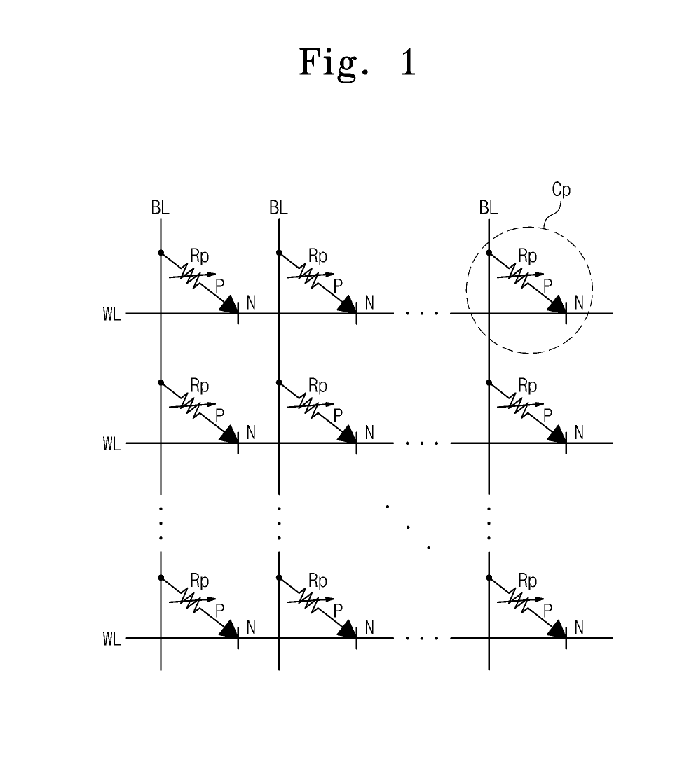

FIG. 1 is a circuit diagram illustrating a portion of a cell array region of a phase change memory device according to exemplary embodiments.

The phase change memory device may be, for example, a data storage device for storing data. As illustrated in FIG. 1, the phase change memory cell array region may include bit lines (BL) and word lines (WL) crossing the bit lines (BL). A plurality of two dimensionally arrayed phase change memory cells Cp are disposed at cross points of the bit lines (BL) and the word lines (WL), respectively. Each of the phase change memory cells Cp may include a phase change resistor Rp and a PN junction diode, which are electrically connected in series. The phase change resistor Rp may include materials capable of changing phase based on an electrical signal, optical signal, or radiation. The phase change resistor Rp may include, for example, a chalcogenide material, such as a GST. The PN junction diode may include, for example, a p-type semiconductor region and an n-type semiconductor region.

The p-type semiconductor region of the PN junction diode may be electrically connected to one end of the phase change resistor Rp, and the other end of the phase change resistor Rp may be electrically connected to one of the bit lines (BL). The n-type semiconductor region of the PN junction diode may be electrically connected to one of the word lines (WL).

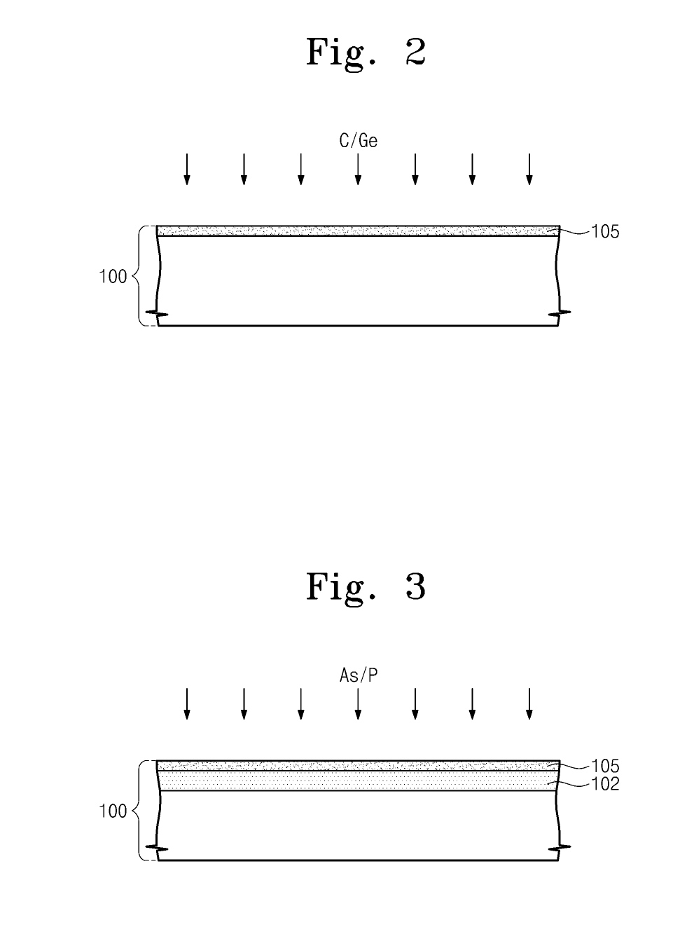

FIGS. 2 through 10 are cross-sectional views illustrating a method of manufacturing a phase change memory device according to exemplary embodiments. Referring to FIG. 2, a substrate 100 may include a first ion-implanted layer 105. The substrate 100 may be, for example, a silicon substrate, a germanium substrate, a silicon-germanium substrate, Silicon-On-Insulator (SOI) substrate, or Germanium-On-Insulator (GOI) substrate. According to exemplary embodiments, the substrate may have a structure so that it comprises a single crystal (e.g., having a crystal lattice structure). In one embodiment, the first ion-implanted layer 105 may be formed by performing a first ion-implanting process implanting, for example, carbon (C) or germanium (Ge) ions on the substrate 100.

According to exemplary embodiments, when the substrate 100 initially has a structure of a single crystal, the first ion-implanted layer 105 may include a silicon and ion-implanted carbon or germanium. As a result, as ion-implanted carbon or germanium atoms are arranged between silicon atoms of a single crystal state, atomic arrangement of the first ion-implanted layer 105 may be changed from the single crystal state to an amorphous state. In certain embodiments, the first ion-implanting process may include an ion-implantation method or a PLAD (Plasma Doping) method. In one embodiment, the first ion-implanting process maintains a doping concentration of the substrate 100 by implanting ions of group 4 elements. In one embodiment, the first ion-implanted layer 105 may be formed from the top surface of the substrate 100 to a distance below the surface of the substrate 100.

Referring to FIG. 3, an impurity region 102 may be formed in the substrate 100. For example, the impurity region 102 may be a high concentration impurity region doped with a dopant of a first conductive type. The first conductive type may be n-type, for example. The impurity region 102 may be formed in an upper portion of the substrate 100. For example, in one embodiment, the impurity region 102 extends from a bottom of the first ion-implanted layer 105 to a particular distance below the surface of the substrate 100. In another embodiment, however, the impurity region 102 may be formed from the top surface of the substrate 100 to a distance below the surface of the substrate 100, such that the impurity region 102 includes the first ion-implanted layer 105.

As such, according to exemplary embodiments, the impurity region 102 may be formed more deeply in the substrate than the first ion-implanted layer 105. The impurity region 102 may be formed by implanting, for example, arsenic or phosphorus ions within the substrate 100. The impurity region 102 may be formed by an ion-implantation method, but is not limited thereby. The first ion-implanted layer 105 formed in the upper portion of the substrate 100 can have an atomic arrangement of an amorphous state, and may include impurities such as arsenic or phosphorus ions. In one embodiment, the first ion-implanted layer 105 has a higher number or greater concentration of arsenic or phosphorus ions than the portion of the impurity region 102 below the first ion-implanted layer.

Note that although the layers are described above and in the figures as having clear boundaries, in certain embodiments, the boundaries between regions may be gradual and not linear step-wise. As such, the impurity region 102 may be thought of as ending not at a rigid line, but at a point where a concentration of impurities 102 is below a particular level. A similar boundary may exist for the first ion-implanted layer 105.

In one embodiment, as described and shown in FIGS. 2 and 3, the first ion-implanted layer 105 is formed first, and then the impurity region 102 is formed second. However, these layers need not be formed in this order. In one embodiment, for example, the impurity region 102 is formed prior to the first ion-implanted layer 105.

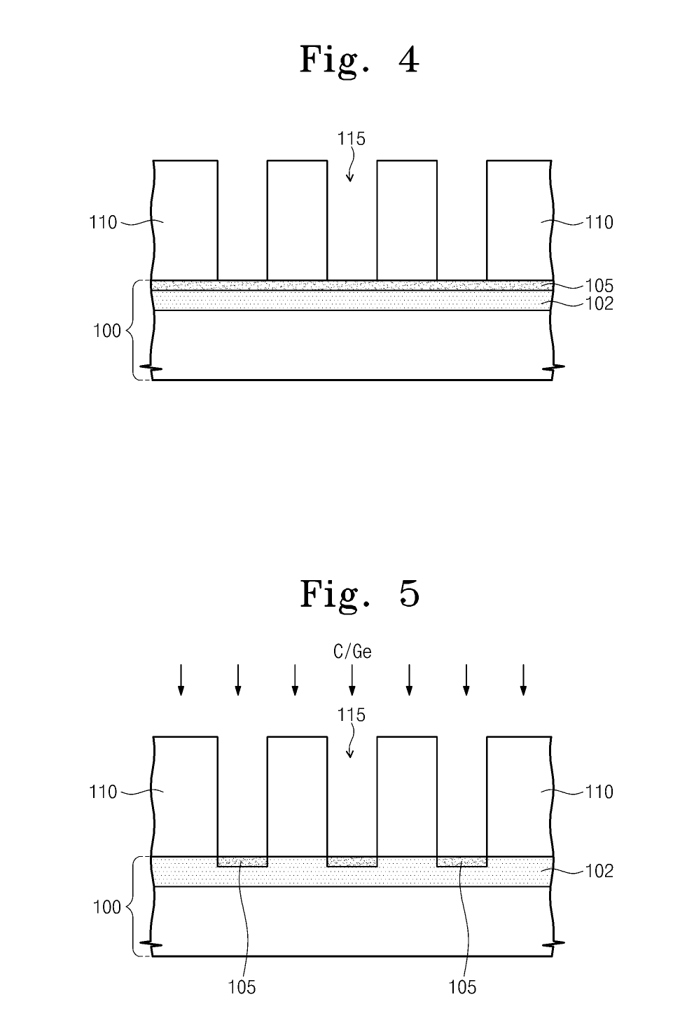

Referring to FIG. 4, an insulating pattern 110 may be formed on the substrate 100. In one embodiment, the insulating pattern 110 may be formed, for example, of HDP (High Density Plasma) oxide layer, USG (Undoped Silicate Glass), or BPSG (Borophospho Silicate Glass). According to exemplary embodiments, the insulating pattern 110 may be formed by forming an insulating layer, and then forming openings 115 exposing the substrate 100 by patterning the insulating layer. The ion-implanted layer 105 of the substrate 100 may be exposed through an opening 115. The opening 115 may be, for example, a hole. The opening 115 may be defined as a region where a PN diode is formed.

Referring to FIG. 5, in one embodiment, the first ion-implanted layer 105 explained in FIG. 2 may be formed after forming the insulating pattern 110. The first ion-implanted layer 105 may be formed by forming the insulating pattern 110 on the substrate 100 including the first impurity region 102, and then performing the first ion-implanting process implanting, for example, carbon or germanium ions. The ion-implanted layer 105 may be formed within the first impurity region 102 exposed by the opening 115.

According to exemplary embodiments, the first ion-implanting process may be performed before forming the insulation pattern 110 or after forming the insulating pattern 110.

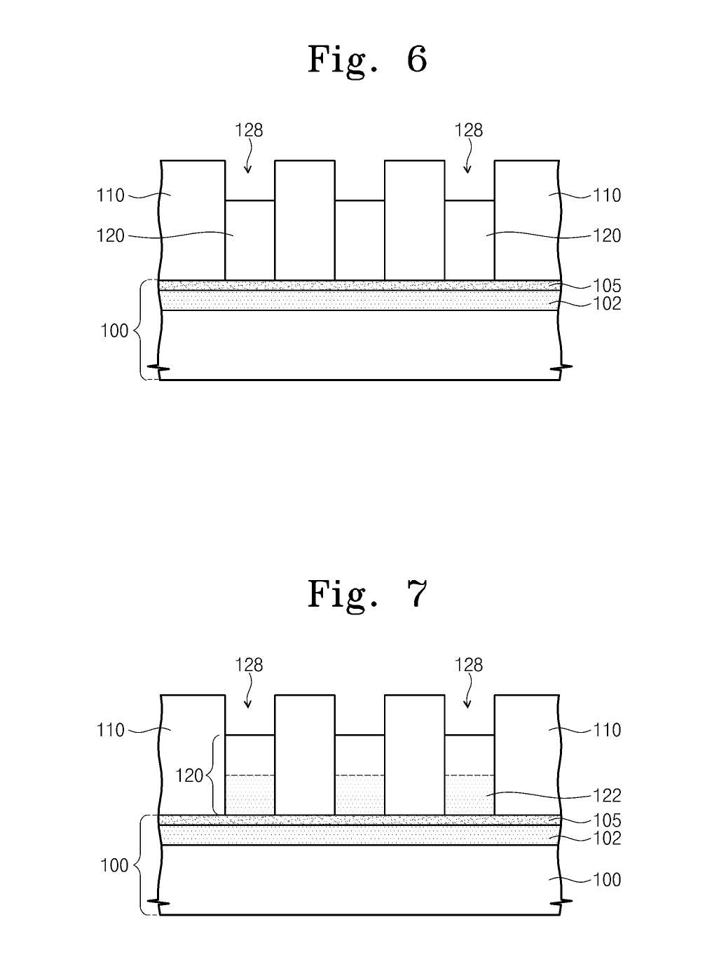

Referring to FIG. 6, a semiconductor layer 120 including a semiconductor material filling the opening 115 may be formed. The semiconductor layer 120 may be formed, for example, using a selective epitaxial growth (SEG) technique. For example, the semiconductor layer 120 may be formed by an in-situ technique reacting silicon-containing source gas, such as SiH2Cl2 or SiH4 using the substrate 100 as a seed. As such, in one embodiment, the semiconductor material that fills the semiconductor layer 120 includes silicon. Alternatively, the semiconductor layer 120 may be formed by Chemical Vapor Deposition (CVD) technique using HCl or DCS (Dichloro silane) gas. According to exemplary embodiments, the upper-most portion of the semiconductor layer 120 may be formed at a lower height than an upper-most portion of the insulating pattern 110 (e.g., a top surface of the semiconductor layer 120 may be lower than a top surface of the insulating pattern 110). As such, the semiconductor layer 120 may be formed in the opening 115 without completely filling the opening 115. A lower electrode (not shown) may be formed in an empty space 128 during following processes.

Referring to FIG. 7, a first doped region 122 may be formed in the semiconductor layer 120. The first doped region 122 may have the first conductive type. According to exemplary embodiments, the first doped region 122 may be simultaneously formed in the process of forming the semiconductor layer 120. For example, the first doped region 122 may be formed as impurities of the first impurity region 102 having the first conductive type of high concentration are diffused by thermal energy produced in the process of forming the semiconductor layer 120 through, for example, an SEG technique. Therefore, in one embodiment, the first doped region 122 has the same first conductive type as the first impurity region 102. In one embodiment, the first ion-implanted layer 105 performs the function of reducing the diffusion of impurities from the first impurity region 102 to the first doped region 122 and vice versa. As such, the first ion-implanted layer 105 can adjust an impurity concentration profile of the first doped region 122 (e.g., it can control a height and concentration of impurities in the first doped region 122).

According to exemplary embodiments, the first doped region 122 may be formed by performing additional heat treatment after forming the semiconductor layer 120. The first doped region 122 may be formed as impurities of the first impurity region 102 having the first conductive type of high concentration are diffused by thermal energy produced by the heat treatment.

The semiconductor layer 120 may have an atomic arrangement of single crystal or crystalline state as a result of thermal energy produced in the process of SEG or additional heat treatment.

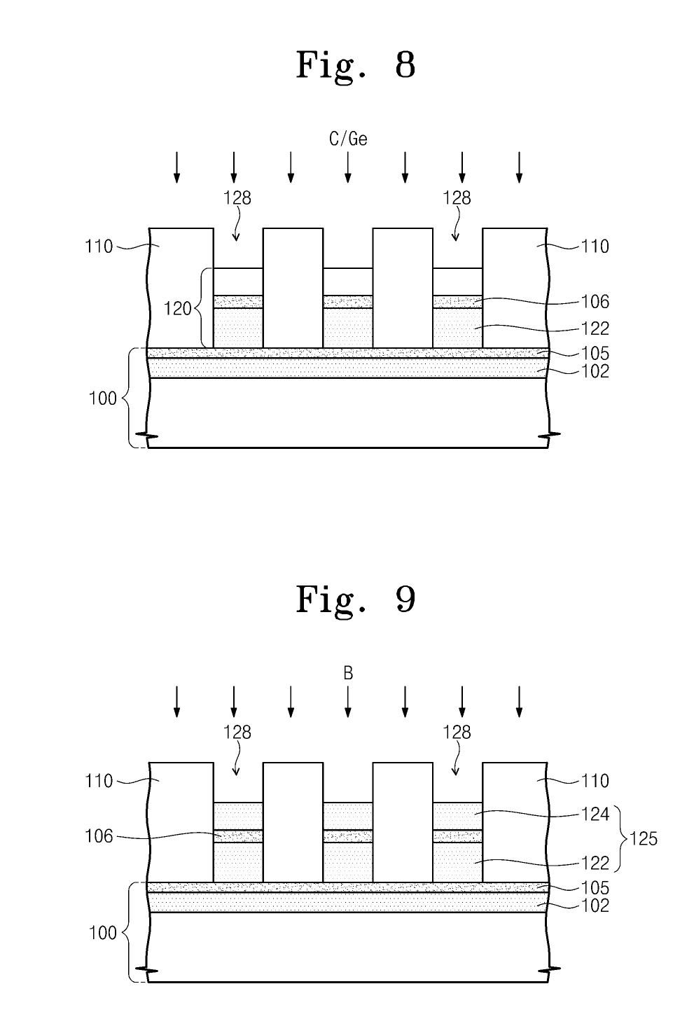

Referring to FIG. 8, a second ion-implanting process implanting carbon or germanium ions may be performed in the semiconductor layer 120. In one embodiment, this process is performed after the semiconductor layer 120 is formed, and after an optional additional heat treatment in the semiconductor layer 120. A second ion-implanted layer 106 in the semiconductor layer 120 may be formed through the second ion-implanting process. The second ion-implanted layer 106 may include, for example, silicon implanted with carbon or germanium ions. Atoms of carbon or germanium ions are arranged between silicon atoms of crystal or crystalline state in the semiconductor layer 120, so the second ion-implanted layer 106 may be changed into an amorphous state. According to exemplary embodiments, implanting group 4 elements in the second ion-implanting process does not significantly affect a doping state of the first doped region 122 in the first semiconductor layer 120.

According to exemplary embodiments, the second ion-implanting process may include ion-implantation method or PLAD (Plasma Doping) method. The second ion-implanted layer 106 may be selectively formed at various depths in the semiconductor layer 120. For example, the second ion-implanted layer 106 may be formed directly on the first doped region 122 (e.g., above and immediately adjacent to the first doped region 122). The second ion-implanted layer 106 may therefore control the concentration profile of impurities in a second doped region. For example, the second ion-implanted layer 106 may limit the impurities that diffuse from the first doped region 122 to the remainder of the semiconductor layer 120. Similarly, if the remainder of the semiconductor layer 120 is doped with other impurities, as will be described below, the second ion-implanted layer 106 may limit those impurities from diffusing into the first doped region 122. In one embodiment, the second ion-implanted layer 106 may be formed in the upper portion of the first semiconductor layer 120 (e.g., in an upper half of the semiconductor layer 120). However, the second ion-implanted layer 106 can be formed at other locations within the first semiconductor layer 120.

Referring to FIG. 9, a second doped region 124 may be formed in the semiconductor layer 120. The second doped region 124 may have a second conductive type contrary to the first conductive type. For example, in one embodiment, where the first doped region 122 is an n-type region, the second doped region 124 is a p-type region. The second doped region 124 may be formed, for example, by implanting boron (B) ions in the semiconductor layer 120.

According to exemplary embodiments, the second doped region 124 may be formed by PLAD (Plasma Doping) method. The second doped region 124 may be formed by doping atoms ionized in the plasma state, which can adjust the doping concentration more easily than conventional ion beam implantation method, and can improve productivity resulting from a short process time. The second doped region 124 may be formed, for example, by using diborane (B2H6) gas or boron trifluoride (BF3) gas in a plasma chamber.

According to exemplary embodiments, the first doped region 122 and the second doped region 124 may be formed in the semiconductor layer 120. The first doped region 122 may be formed in the lower portion of the semiconductor layer 120 and the second doped region 124 may be formed in the upper portion of the semiconductor layer 120. The semiconductor layer 120 in which the first doped region 122 and the second doped region 124 are formed may go through heat treatment to form the first doped region 122 and the second doped region 124. The semiconductor layer 120 may include a PN junction diode 125 including the first doped region 122 and the second doped region 124 having opposite conductive types. The PN junction diode 125 may play a role, for example, as a switch of phase change memory device.

Referring to FIG. 10, a lower electrode 130 may be formed on the PN junction diode 125. The lower electrode 130 may be formed in the empty space of the opening 115 (128 of FIG. 9). The lower electrode 130 may include conductive materials, such as for example, TiN. A phase change layer 140 may be formed on the lower electrode 130. According to exemplary embodiments, the phase change layer 140 may be formed in an insulating interlayer 145. The phase change layer 140 may include a material that changes phase based on a current applied. A contact 155 and an electrode 160 may be formed on the phase change layer 140. The contact 155 and electrode 160 may include conductive materials.

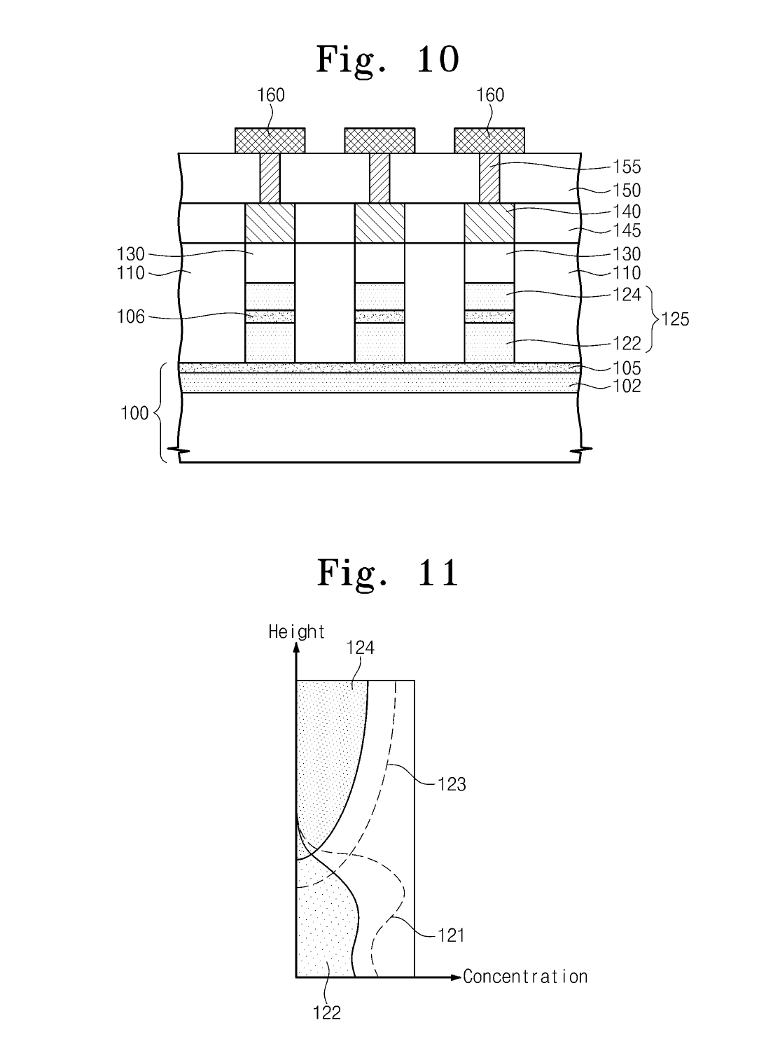

FIG. 11 is a graph of exemplary doping concentration profiles according to the height of the PN junction diode.

Referring to FIG. 11, the doping concentration of the first and the second doped region 122, 124 including the PN junction diode (125 of FIG. 10) may have specified profiles. The first doped region 122 may be formed as dopants of the first impurity region (102 of FIG. 10) having the first conductive type of high concentration are diffused by thermal energy produced in the process of forming the semiconductor layer 120 through, for example, an SEG method or in the process of additional heat treatment. The second doped region 124 may be formed by diffusing dopants of the second conductive type into the second doped region 124 using, for example, a PLAD method. According to conventional technologies, it is difficult to adjust the doping concentration of the first and the second doped regions 122, 124 due to difficulty in controlling the diffusion of the first and the second doped regions 122, 124. For example, if the diffusion of the doped regions is sufficiently progressed according to the conventional technologies, the first and the second doped regions 121, 123 (shown in FIG. 11) having thick doping concentration profile throughout greater heights may be formed and may have a broadened connection area. Such a doping concentration profile may increase operating voltage (Von) and off current of the phase change memory device and may result in decreased efficiency of the phase change memory device.

According to exemplary embodiments, the doping concentration of the first and the second doped regions 122, 124 may be lower compared to conventional technologies. Furthermore, the height to which doping occurs may be lower as well. As a result, the connection area of the first and the second doped regions 122, 124 may be narrowed and may have a lower concentration of impurities. As the first ion-implanted layer 105 is formed through the first ion-implanting process performed before forming the first doped region 122, ion-implanted carbon or germanium atoms are arranged between silicon atoms of a single crystal state in the substrate 100, so arrangement of silicon atoms may be changed from the single crystal state to an amorphous state. As the diffusion of doping areas by thermal energy progresses slowly, the diffusion may be decreased by the first ion-implanted layer 105. Similarly, as the second ion-implanted layer 106 of FIG. 10 is formed through the second ion-implanting process performed before forming the second doped region 124, the doping concentration of the second doped region 124 may be controlled to decrease its diffusion. The doping concentration of impurities according to the height of the first and the second doped regions 122, 124 may be lower compared to conventional technologies, so the PN junction diode having a more shallow junction may be formed. As a result, device efficiency may be increased by decreasing the operating voltage and off current of phase change memory devices including the PN junction diode 125 of FIG. 10.

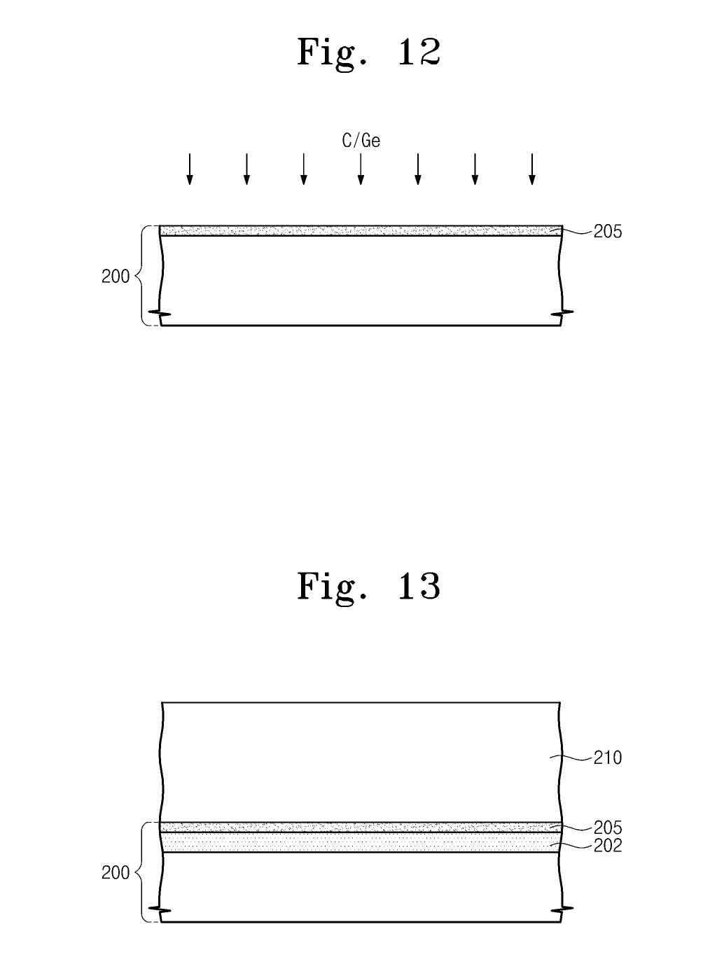

FIGS. 12 through 17 are plan views and cross-sectional views illustrating a method of manufacturing phase change memory device according to exemplary embodiments.

Referring to FIG. 12, a first ion-implanting process implanting, for example, carbon ions or germanium ions may be performed in a substrate 200. Through the first ion-implanting process, a first ion-implanted layer 205 may be formed in the upper portion of the substrate 200 (e.g., extending from a top surface of substrate 200 into the substrate 200).

Referring to FIG. 13, an impurity region 202 may be formed in the substrate 200. The impurity region 202 may be a first conductive type region. The first conductive type may be n-type, for example. In one embodiment, the first ion-implanted layer 205 is formed before the impurity region 202. However, the first ion-implanted layer 205 may alternatively be formed after the impurity region 202. An insulating layer 210 may be formed on the substrate 200.

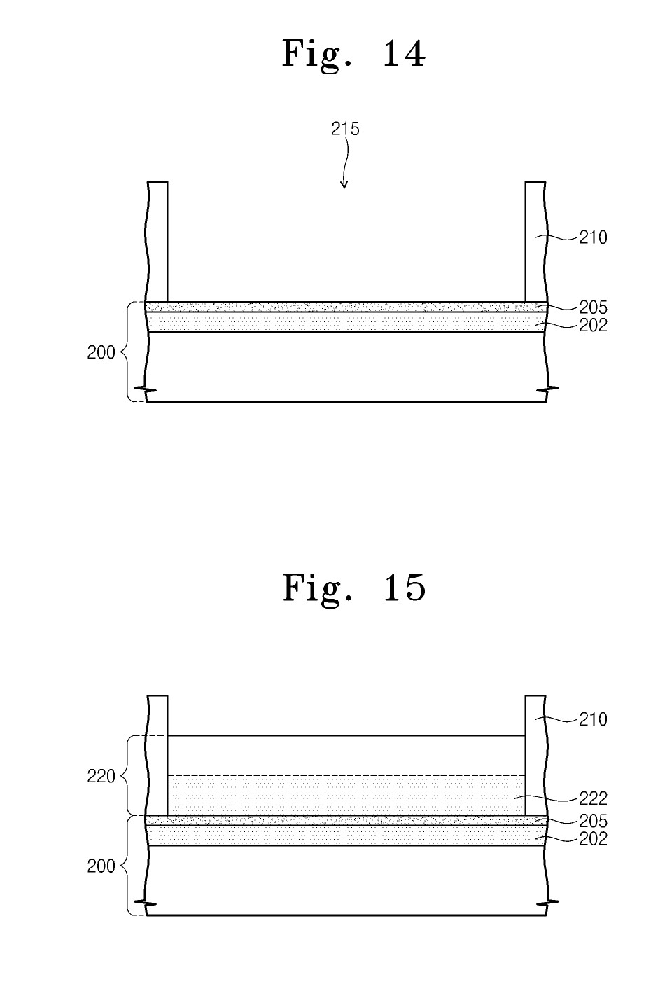

Referring to FIG. 14, a trench 215 exposing the substrate 200 may be formed by patterning the insulating layer 210. The substrate 200 of the area where a PN junction diode is formed may be exposed by the trench 215.

Referring to FIG. 15, a semiconductor layer 220 filling the trench 215 may be formed. The semiconductor layer 220 may be formed, for example, by performing an SEG technique using the exposed substrate 200 as a seed. The semiconductor layer 220 may include a first doped region 222 of the first conductive type the same as the impurity region 202.

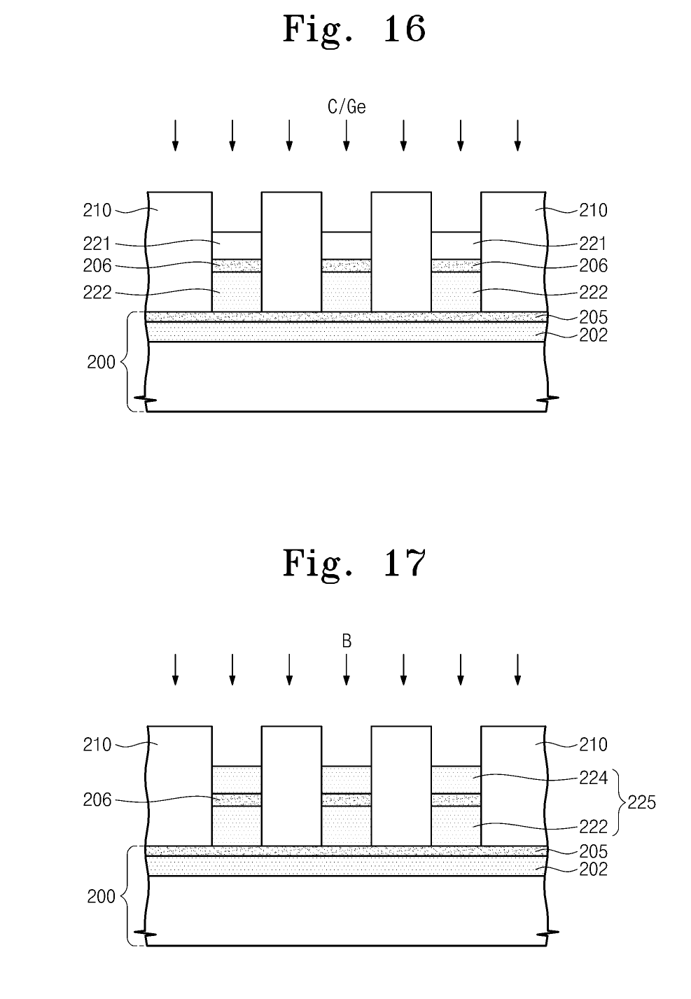

Referring to FIG. 16, semiconductor patterns may be formed by patterning the semiconductor layer 220. The semiconductor patterns 221 may correspond to the semiconductor layer 120 explained in FIG. 1 through 10. An insulating layer 210 filling spaces between the first semiconductor patterns 221 may be formed, and then a second ion-implanting process implanting, for example, carbon ions or germanium ions in the first semiconductor patterns 221 may be performed. Through the second ion-implanting process, a second ion-implanted layer 206 may be formed.

Referring to FIG. 17, a second doped region 224 may be formed by performing an ion-implanting process using plasma in the semiconductor patterns 221. The second doped region 224 may have a second conductive type contrary to the first conductive type. For example, the second doped region 224 may be formed by implanting boron ions in the semiconductor layer 120. Therefore, the first and second doped regions 222, 224 may be a PN junction diode and play a role as a switch of phase change memory device.

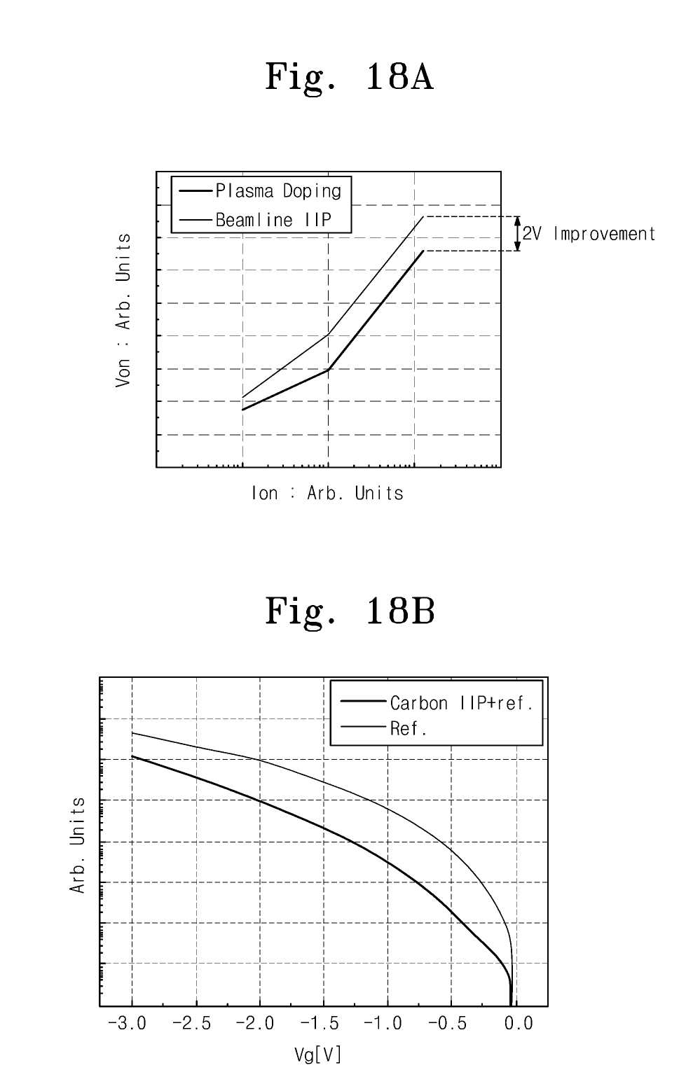

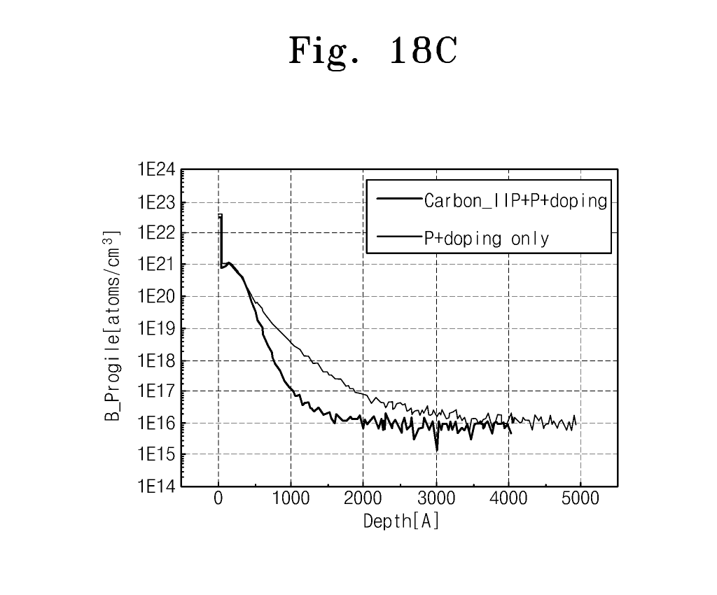

FIGS. 18a through 18c are graphs illustrating characteristics of a phase change memory device according to exemplary embodiments.

FIG. 18a is a graph of an operating voltage (Von) according to current in a case of forming the second doped region using plasma. As explained in FIG. 17, the second doped region 224 may be formed by implanting boron (B) ions on the semiconductor layer 120 through an ion-implanting process using plasma. Compared to an ion beam implantation method of conventional technology, an ion-implanting process using plasma can easily adjust the doping concentration and improve productivity as it has a short process time. Referring to FIG. 18a, in one embodiment, the second doped region 124 formed by using plasma has a lower operating voltage at a specific operating current than the doped region formed by using an ion beam implantation method. Phase change memory devices according to the exemplary embodiments may therefore have increased efficiency by acquiring an adequate operating voltage even for a lower current.

FIG. 18b is a graph of off current according to voltage in case of the first ion-implanted layer before forming the first doped region. As explained in FIG. 2, after forming the first ion-implanted layer 105 by implanting carbon ions or germanium ions on the substrate 100, the first doped region 122 may be formed. As the first ion-implanted layer 105 has an atomic arrangement of an amorphous state, it reduces the diffusion of impurities into the first doped region 122 and accomplishes a PN junction diode 125 having a shallow junction. Referring to FIG. 18b, the efficiency of a phase change memory device according to the exemplary embodiments may be increased by reducing an off current at a specific voltage.

FIG. 18C is a graph of the doping concentration according to the depth in the case of forming the second ion-implanted layer before forming the second doped region. As explained in FIG. 8, the second ion-implanted layer 106 may be formed by implanting carbon ions or germanium ions in the semiconductor layer 120 after the first doped region 122 is formed, after which the second doped region 124 may be formed. As the second ion-implanted layer 106 has the atomic arrangement of an amorphous state, it controls the doping concentration by reducing the doping concentration. Referring to FIG. 18c, the exemplary embodiments have a lower concentration gradient than the method forming the second doped region by conventional technology. Therefore, the PN junction diode 125 according to the exemplary embodiments can have a shallow junction, thereby increasing efficiency of a phase change memory device including the shallow junction.

The embodiments and methods described above can be used in various different types of semiconductor memory devices. For example, the semiconductor memory device may include Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-Level Fabricated Package (WFP), or Wafer-Level Processed Stack Package (WSP).

A semiconductor memory device according to the exemplary embodiments may be in the form of a package that may include one or more controllers and/or logic devices controlling the semiconductor memory device.

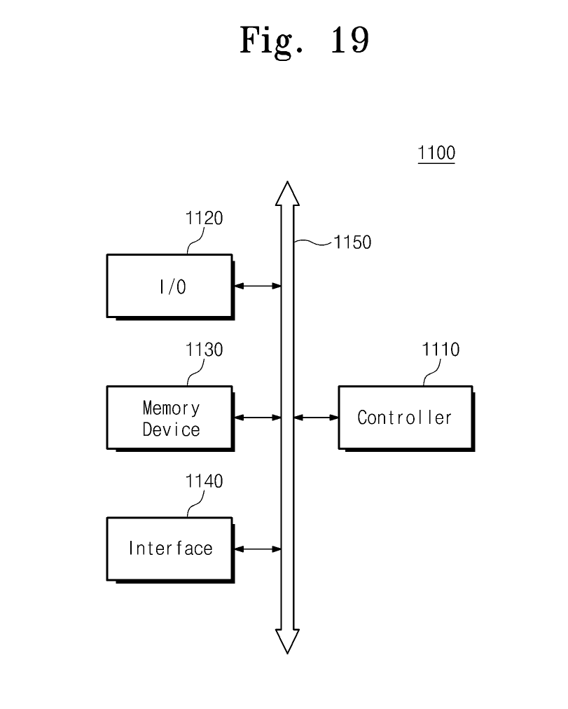

FIG. 19 is a schematic block diagram illustrating an example of a computing system including a semiconductor memory device according to the exemplary embodiments.

Referring to FIG. 19, an electronic system 1100 according to one embodiment may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller, or another logic device. The other logic device may have a similar function to any one of the microprocessor, the digital signal processor, and the microcontroller. The I/O unit 1120 may include a keypad, a keyboard, and/or a display unit. The memory device 1130 may store data and/or commands. The memory device 1130 may include at least one of the phase change memory devices and/or data storage devices according to the embodiments described above. The memory device 1130 may further include other types of semiconductor memory devices, which are different from the semiconductor memory devices described above. For example, the memory device 1130 may further include a non-volatile memory device and/or a static random access memory (SRAM) device. In one embodiment, the interface unit 1140 may transmit electrical data to a communication network or may receive electrical data from a communication network. The interface unit 1140 may be operated by wireless or cable. For example, the interface unit 1140 may include an antenna for wireless communication or a transceiver for cable communication. Although not shown in the drawings, the electronic system 1100 may further include a fast DRAM device and/or a fast SRAM device, which acts as a cache memory for improving an operation of the controller 1110.

The electronic system 1100 may be applied, for example, to a personal digital assistant (PDA), a portable computer, a web tablet, a wireless phone, a mobile phone, a digital music player, a memory card, or other electronic products. The other electronic products may receive or transmit information data, for example, by wired or wireless signals.

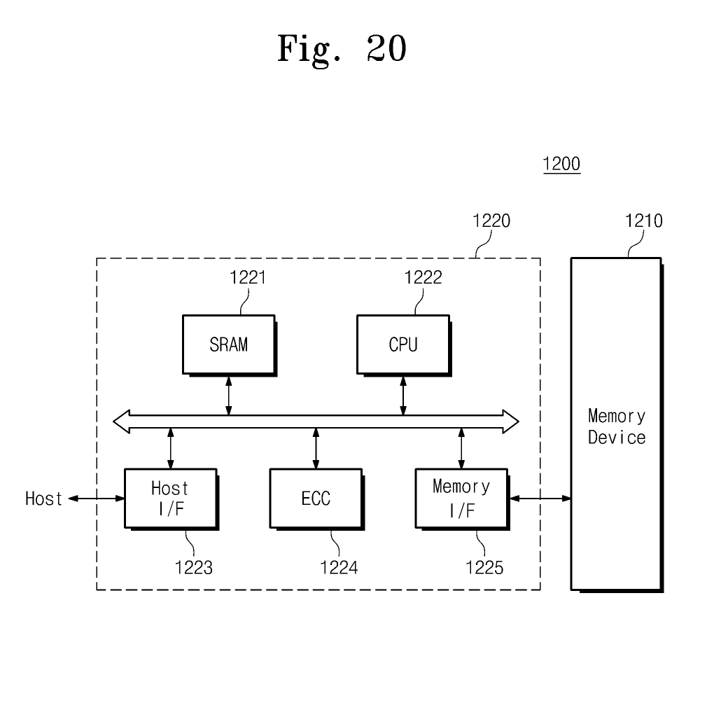

FIG. 20 is a schematic block diagram illustrating an example of memory cards including memory devices according to exemplary embodiments.

Referring to FIG. 20, a memory card 1200 according to one embodiment may include a memory device 1210. The memory device 1210 may include at least one of the semiconductor memory devices according to the embodiments mentioned above. In other embodiments, the memory device 1210 may further include other types of semiconductor memory devices, which are different from the semiconductor memory devices according to the embodiments described above. For example, the memory device 1210 may further include a non-volatile memory device and/or a static random access memory (SRAM) device. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used, for example, as a portable data storage card. Alternatively, the memory card 1200 may be realized as solid state disks (SSD) which are used as hard disks of computer systems.

While the disclosure has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1. A method of forming a phase change memory device, the method comprising:
forming a first ion-implanted layer having an amorphous state in a substrate;
forming an impurity region of a first conductive type in the substrate;
forming a semiconductor pattern on the substrate;
forming a first doped region of the first conductive type in the semiconductor pattern;
forming a second doped region of a second conductive type contrary to the first conductive type in the semiconductor pattern,
wherein the first ion-implanted layer is formed by implanting carbon ions or germanium ions in the substrate.

2. The method of claim 1, further comprising forming a second ion-implanted layer having an amorphous state in the semiconductor pattern, the second ion-implanted layer formed at a different height from the first ion-implanted layer.

3. The method of claim 1, wherein the second doped region is formed after the second ion-implanted layer is formed.

4. The method of claim 3, wherein the first doped region is formed after the first ion-implanted layer is formed.

5. The method of claim 1, wherein the first doped region is formed by diffusion of dopants of the first conductive type from the impurity region to the semiconductor pattern,
wherein the first ion-implanted layer controls the diffusion of the dopants into the first doped region.

6. The method of claim 1, wherein the first ion-implanted layer is formed by ion beam implantation or an ion-implanting method using plasma.

7. The method of claim 1, wherein forming the semiconductor pattern comprises:
forming an insulating layer on the substrate;
forming a hole exposing the substrate by patterning the insulating layer; and
forming the semiconductor pattern filling the hole by performing an epitaxial process.

8. The method of claim 7, wherein forming the first ion-implanted layer is performed after forming the hole.

9. The method of claim 1, wherein the first doped region is formed at the same time as the semiconductor pattern.

10. The method of claim 2, wherein the second ion-implanted layer is formed by performing an ion-implanting method using plasma.

11. The method of claim 1, wherein forming the first ion-implanted layer is performed before forming the impurity region, and wherein the first ion-implanted layer extends from a surface of the substrate into the substrate, and the impurity region extends from the surface of the substrate into the substrate and extends a greater distance into the substrate than the first ion-implanted layer.

12. The method of claim 1, further comprising:
forming a PN junction diode,
wherein the PN junction diode is formed by the first doped region and the second doped region.

13. A method of manufacturing a phase-change memory device, the method comprising:
providing a substrate;
forming an impurity region of a first conductive type in the substrate, the impurity region extending from the top surface of the substrate into the substrate;
forming a semiconductor pattern on the substrate;
forming a first doped region of the first conductive type in the semiconductor pattern;
forming a layer having an amorphous state in the semiconductor pattern; and
forming a second doped region of a second conductive type contrary to the first conductive type in the semiconductor pattern,
wherein the layer controls the amount of doping that occurs in at least the second doped region.

14. The method of claim 13, wherein the layer is a second layer, and further comprising:
forming a first layer from a top surface of the substrate into the substrate, the first layer having an amorphous state; and
forming an impurity region of a first conductive type in the substrate, the impurity region extending from the top surface of the substrate into the substrate, and extending a further distance into the substrate than the first layer,
wherein the second layer is formed at a different height from the first layer.

15. The method of claim 14, wherein the first doped region is formed after the first layer is formed, and the second doped region is formed after the second layer is formed.

16. The method of claim 14, wherein the first doped region is formed by diffusion of dopants of the first conductive type from the impurity region to the semiconductor pattern,
wherein the first layer is an ion-implanted layer that controls the diffusion of the dopants into the first doped region.

17-20. (canceled)
